(19) United States
(12) Patent Application Publication
(10) Pub. No.: US 2026/0312593 A1
(43) Pub. Date: Oct. 8, 2026

(54) Phase-Locked Loop Circuit

(71) Applicant: NOVATEK Microelectronics Corp., Hsin-Chu (TW)

(72) Inventors: Yi-Wen Hung, Hsin-Chu (TW); Bing-Syun Wu, Hsinchu County (TW); Tung-Cheng Hsin, Hsinchu City (TW)

(73) Assignee: NOVATEK Microelectronics Corp., Hsin-Chu (TW)

(21) Appl. No.: 19/403,206

(22) Filed: Nov. 27, 2025

Related U.S. Application Data
(60) Provisional application No. 63/784,957, filed on Apr. 7, 2025.

(51) Int. Cl. H03L 7/099; H03L 7/091; H03L 7/107; H03M 3/00

(52) U.S. Cl. CPC H03L 7/0991; H03L 7/091; H03L 7/107; H03M 3/37

(57) ABSTRACT

A phase-locked loop circuit includes a digital control oscillator, configured to generate an output clock signal according to at least one control code generated using at least one phase error signal; and a phase detector, configured to generate the at least one phase error signal according to a rising edge difference and a rising edge lead-lag relation between a rising edge of a first clock signal and a corresponding edge of an edge alignment corrected feedback signal; wherein the edge alignment corrected feedback signal is generated based on the output clock signal.

### CROSS REFERENCE TO RELATED APPLICATIONS

This application claims the benefit of U.S. Provisional Application No. 63/784,957, filed on Apr. 7th, 2025. The content of the application is incorporated herein by reference.

### BACKGROUND OF THE INVENTION

### 1. Field of the Invention

The present invention relates to a phase-locked loop circuit, and more specifically, to a phase-locked loop circuit that implements an analog phase-locked loop circuit in a digital manner.

### 2. Description of the Prior Art

The display technology field typically uses an analog phase-locked loop (PLL) circuit or a digital counter-based frequency detection circuit to generate the required high-precision clock. The analog PLL circuit includes a phase-frequency detector, a loop filter, a voltage-controlled oscillator (VCO), and a frequency divider to provide an output clock aligned with a reference clock. However, different specifications require redesigning the analog PLL circuit, resulting in a long development time. For example, to adjust the lock time, the loop filter's resistor and capacitor values must be redesigned to change the bandwidth. Alternatively, the VCO and the frequency divider must be redesigned to adjust the output clock and reference clock.

The digital counter-based frequency detection circuit includes a digital counter circuit and a digital VCO to provide an output clock correlated with the reference clock. Compared to the analog PLL circuit, the digital counter-based frequency detection circuits have the advantage of being faster to implement. However, the digital counter-based frequency detection circuit has the following limitations: the output clock is not phase-aligned with the reference clock, the output clock has high noise, and the lock time is longer. Therefore, how to combine the advantages of the analog phase-locked loop circuit and the digital counting frequency detection circuit has become one of the goals of the industry.

### SUMMARY OF THE INVENTION

It is therefore an objective of the present invention to provide a phase-locked loop circuit in a digital manner for providing an output clock. This helps to combine the advantages of the analog phase-locked loop circuit and the digital counting frequency detection circuit.

An embodiment of the present invention discloses a phase-locked loop (PLL) circuit, comprising: a digital control oscillator, configured to generate an output clock signal according to at least one control code generated using at least one phase error signal; and a phase detector, configured to generate the at least one phase error signal according to a rising edge difference and a rising edge lead-lag relation between a rising edge of a first clock signal and a corresponding edge of an edge alignment corrected feedback signal; wherein the edge alignment corrected feedback signal is generated based on the output clock signal.

An embodiment of the present invention discloses a phase detector, for a phase-locked loop (PLL) circuit, comprising: a counter, configured to generate an edge alignment corrected feedback signal according to an output clock signal of the PLL circuit; an edge sampler, configured to generate a first sampled signal corresponding to a rising edge of a first clock signal of the PLL circuit and a second sampled signal corresponding to a rising edge lead-lag relation between the rising edge of the first clock signal and a corresponding edge of the edge alignment corrected feedback signal according to the first clock signal and the output clock signal; and a phase quantization circuit, coupled to the counter and the edge sampler, configured to generate at least one phase error signal according to the first sampled signal, the second sampled signal and the edge alignment corrected feedback signal.

These and other objectives of the present invention will no doubt become obvious to those of ordinary skill in the art after reading the following detailed description of the preferred embodiment that is illustrated in the various figures and drawings.

### BRIEF DESCRIPTION OF THE DRAWINGS

FIG. 1 is a schematic diagram of a phase-locked loop circuit according to an embodiment of the present invention.

FIG. 2 is a schematic diagram of a phase detector according to an embodiment of the present invention.

FIG. 3 is a schematic diagram of an edge sampler according to an embodiment of the present invention.

FIG. 4 are waveform diagrams of a first clock signal, a first sampled signal, and an edge alignment corrected feedback signal according to an embodiment of the present invention.

FIG. 5 is a schematic diagram of an edge sampler according to another embodiment of the present invention.

FIG. 6 is a schematic diagram of a phase-locked loop circuit according to another embodiment of the present invention.

FIG. 7 is a waveform diagram of at least one first phase error code and at least one second phase error code according to an embodiment of the present invention.

FIG. 8 is a schematic diagram of a digital control oscillator according to another embodiment of the present invention.

FIG. 9 is a schematic diagram of a phase-locked loop circuit according to another embodiment of the present invention.

### DETAILED DESCRIPTION

Certain terms are used throughout the description and following claims to refer to particular components. As one skilled in the art will appreciate, hardware manufacturers may refer to a component by different names. This document does not intend to distinguish between components that differ in name but not function. In the following description and in the claims, the terms “include” and “comprise” are utilized in an open-ended fashion, and thus should be interpreted to mean “include, but not limited to”. Also, the term “couple” is intended to mean either an indirect or direct electrical connection. Accordingly, if one device is coupled to another device, that connection may be through a direct electrical connection, or through an indirect electrical connection via other devices and connections.

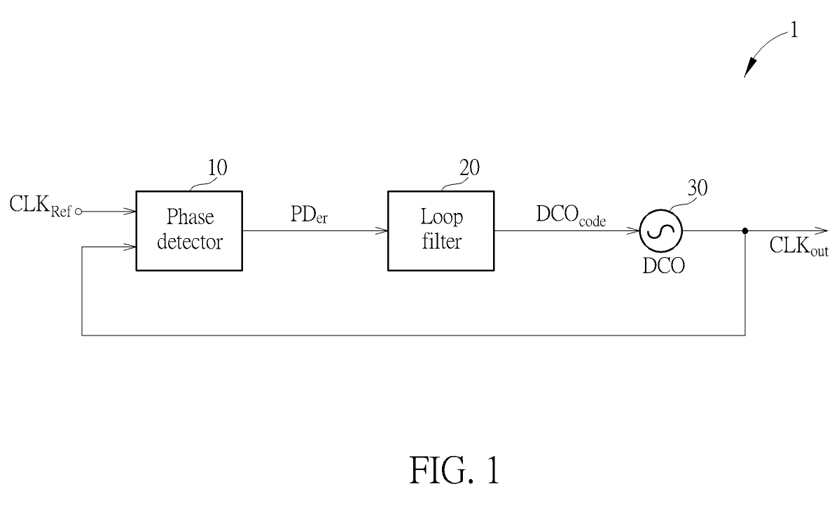

Please refer to FIG. 1. FIG. 1 is a schematic diagram of a phase-locked loop circuit 1 according to an embodiment of the present invention. The phase-locked loop circuit 1 includes a phase detector 10, a loop filter 20, and a digital control oscillator 30. The digital control oscillator 30 generates an output clock signal CLKₒᵤₜaccording to at least one control code DCOcode generated from at least one phase error signal PDₑᵣ. The phase detector 10 generates at least one phase error signal PDer according to a rising edge difference and a rising edge lead-lag relation between a rising edge of a first clock signal CLK_{Ref} and a corresponding edge of an edge alignment corrected feedback signal. It should be noted that the edge alignment corrected feedback signal is generated according to the output clock signal CLKₒᵤₜ. In an embodiment, the loop filter 20 is coupled between the phase detector 10 and the digital control oscillator 30 and configured to generate at least one first phase error code as at least one control code DCO_{code}according to at least one phase error signal PDₑᵣ.

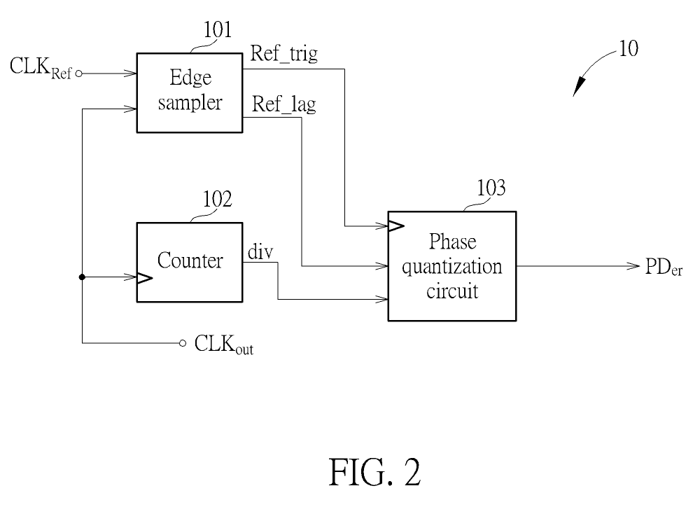

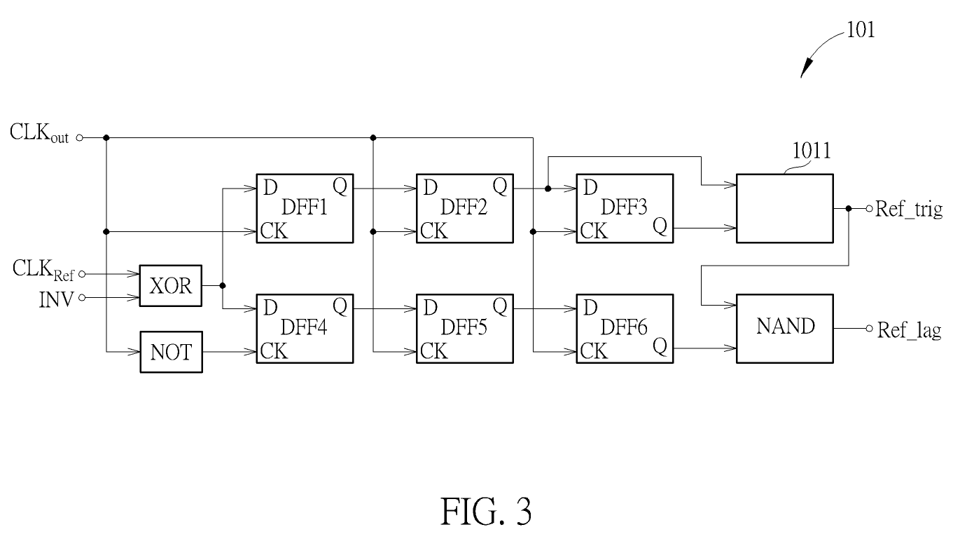

Please refer to FIG. 2. FIG. 2 is a schematic diagram of the phase detector 10 according to an embodiment of the present invention. The phase detector 10 includes an edge sampler 101, a counter 102, and a phase quantization circuit 103. The edge sampler 101 is configured to generate a first sampled signal Ref_trig corresponding to the rising edge and a second sampled signal Ref_lag corresponding to the rising edge lead-lag relation according to the first clock signal CLK_{Ref}and the output clock signal CLKₒᵤₜ. Please refer to FIG. 3, which is a schematic diagram of the edge sampler 101 according to an embodiment of the present invention. The edge sampler 101 includes D flip-flop circuits DFF1-DFF6, an inverter (NOT gate) circuit, an exclusive OR (XOR) gate circuit, a NAND gate circuit, and a determination circuit 1011. Two input terminals of the XOR gate receive the first clock signal CLK_{Ref}and a switching signal INV, respectively, and are configured to switch the phase detector 10 to detect the rising edge or falling edge of the first clock signal CLK_{Ref}. Specifically, when the switching signal INV = 0, the phase detector 10 can detect the rising edge of the first clock signal CLK_{Ref}, and alternatively, when the switching signal INV = 1, the phase detector 10 can detect the falling edge of the first clock signal CLK_{Ref}. Note that, for the sake of simplicity, the following examples use the switching signal INV = 0. Furthermore, the operating principles of D flip-flop circuit, inverter, XOR gate and NAND gate are well-known in the field and are not repeated here

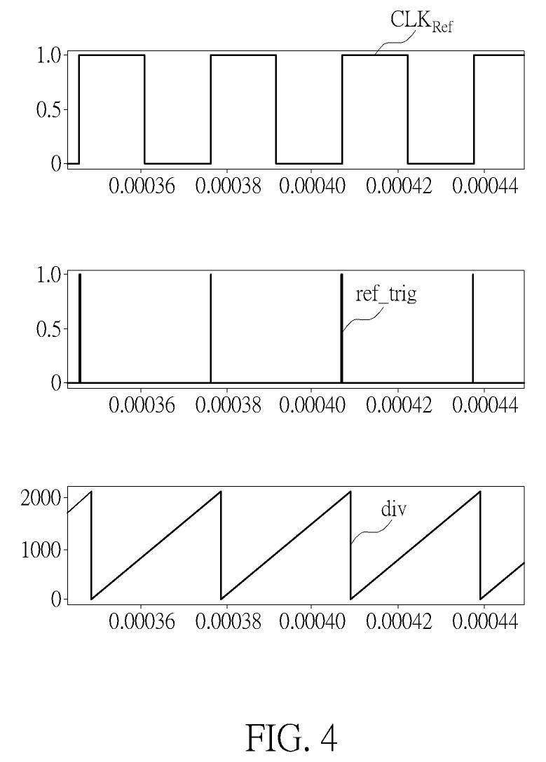

In the edge sampler 101, each of the clock signal terminals of the DFF circuits DFF1-DFF3 respectively receive the output clock signal CLKₒᵤₜ. The data input terminal of DFF circuit DFF1 is coupled to the output terminal of the XOR circuit, the data input terminal of DFF circuit DFF2 is coupled to the data output terminal of DFF circuit DFF1, and the data input terminal of DFF circuit DFF3 is coupled to the data output terminal of DFF circuits DFF2. The two input terminals of the determination circuit 1011 are respectively coupled to the data output terminals of DFF circuit DFF2 and DFF circuit DFF3. In this way, the determination circuit 1011 can determine the phase of the rising edge of the first clock signal CLK_{Ref} and output the first sampled signal Ref_trig accordingly. Please refer to FIG. 4, which illustrates waveform diagrams of the first clock signal CLK_{Ref}, the first sampled signal Ref_trig, and the edge alignment corrected feedback signal div according to an embodiment of the present invention. As shown in FIG. 4, the first sampled signal Ref_trig = 1 represents the phase of the rising edge of the first clock signal CLK_{Ref}.

Furthermore, the clock signal input of DFF circuit DFF4 receives the output clock signal CLKₒᵤₜ through the inverter circuit. The clock signal inputs of DFF circuits DFF5, DFF6 each receive the output clock signal CLKₒᵤₜ. The data input terminal of DFF circuit DFF4 is coupled to the output terminals of the XOR circuit, the data input terminal of DFF circuit DFF5 is coupled to the data output terminals of DFF circuit DFF4, and the data input terminal of DFF circuit DFF6 is coupled to the data output terminal of DFF circuit DFF5. The two input terminals of the NAND gate circuit are respectively coupled to the output terminal of determination circuit 1011 and the data output terminal of DFF circuit DFF6. In this way, the NAND gate circuit can determine the rising edge lead-lag relation between the rising edge of the first clock signal CLK_{Ref} and a corresponding rising edge of the output clock signal CLKₒᵤₜ, and output the second sampled signal Ref_lag accordingly. For example, when the second sampled signal Ref_lag = 1, the rising edge of the first clock signal CLK _{Ref}leads the phase of the corresponding rising edge of the output clock signal CLKₒᵤₜ, and alternatively, when the second sampled signal Ref_lag = 0, the phase of the rising edge of the first clock signal CLK_{Ref}lags behind the phase of the corresponding rising edge of the output clock signal CLKₒᵤₜ.

Please refer to FIG. 2. The counter 102 is configured to generate the edge alignment corrected feedback signal div according to the output clock signal CLKₒᵤₜ. The phase quantization circuit 103 is coupled to the counter 102 and the edge sampler 101, and is configured to generate the at least one phase error signal PDₑᵣaccording to the first sampled signal Ref_trig, the second sampled signal Ref_lag, and the edge alignment corrected feedback signal div. Specifically, the phase quantization circuit 103 can record the value of the rising edge of the edge alignment corrected feedback signal div when the first sampled signal Ref_trig = 1, and calculate the at least one phase error signal PDₑᵣof the first clock signal CLK_{Ref}and the output clock signal CLKₒᵤₜ after frequency division according to the rising edge value and the second sampled signal Ref_lag. It should be noted that by utilizing the rising edge lead-lag relation represented by the second sampled signal Ref_lag, the phase quantization circuit 103 can generate the at least one phase error signal PDₑᵣ with improved resolution. Please refer to FIG. 4, where the edge alignment corrected feedback signal div = 0 represents the phase of the corresponding rising edge of the output clock signal CLKₒᵤₜ. Furthermore, the difference between the rising edge of the edge alignment corrected feedback signal div corresponding to the first sampled signal Ref_trig=1 and 0 represents the phase difference between the first clock signal CLKRef and the output clock signal CLKout after frequency division.

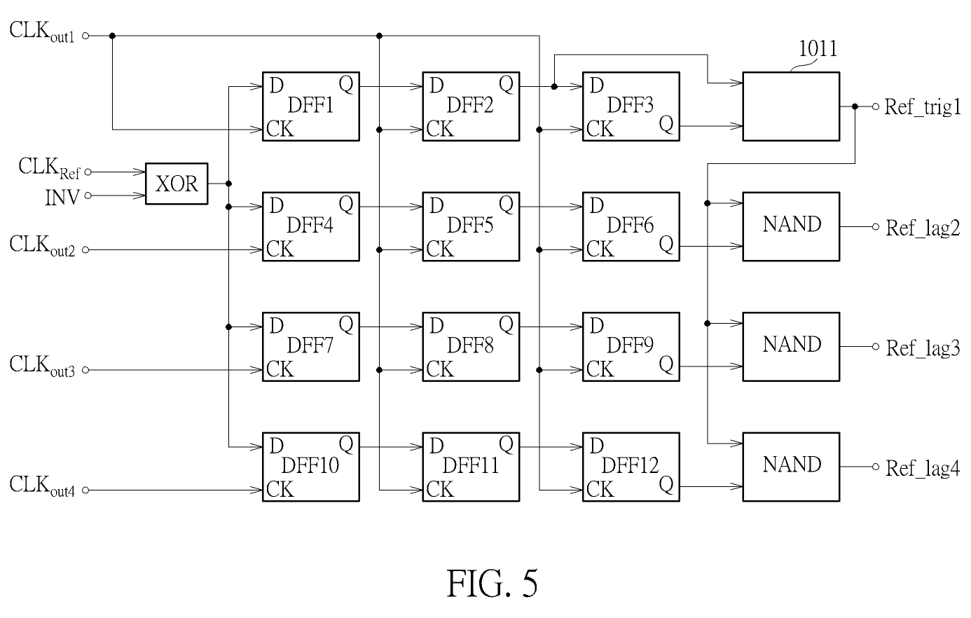

It should be noted that FIG. 3 is only an embodiment of the present invention, and those skilled in the art may make appropriate adjustments according to the system requirements. For example, please refer to FIG. 5, which is a schematic diagram of the edge sampler 101 according to another embodiment of the present invention. In an embodiment, the digital control oscillator 30 can generate four phases of the output clock signals CLKₒᵤₜ₁ - CLKₒᵤₜ₄. The edge sampler 101 can determine the phase of the rising edge of the first clock signal CLK_{Ref}. Furthermore, the edge sampler 101 can determine the rising edge lead-lag relation between the phase of the rising edge of the first clock signal CLK_{Ref}and the corresponding rising edge of the multiple output clock signals CLKₒᵤₜ₁ - CLKₒᵤₜ₄, and output multiple second sampled signals Ref_lag1 to Ref_lag3 accordingly. In this way, by using the rising edge lead-lag relation represented by the multiple second sampled signals Ref_lag1 to Ref_lag3, the phase quantization circuit 103 can generate the at least one phase error signal PDₑᵣ with improved resolution.

Furthermore, the loop filter 20 converts the at least one phase error signal PDₑᵣ into the at least one control code DCO_{code} to control the digital control oscillator 30 to generate an output clock signal CLKₒᵤₜ. Specifically, the loop filter 20 can utilize s-domain to z-domain conversion methods such as a bilinear transformation method or a pulse-invariant method to implement the analog loop filter in a digital manner, but is not limited thereto. It should be noted that the operating principles of the bilinear transformation method or the pulse-invariant method are well known in the art and are not repeated here.

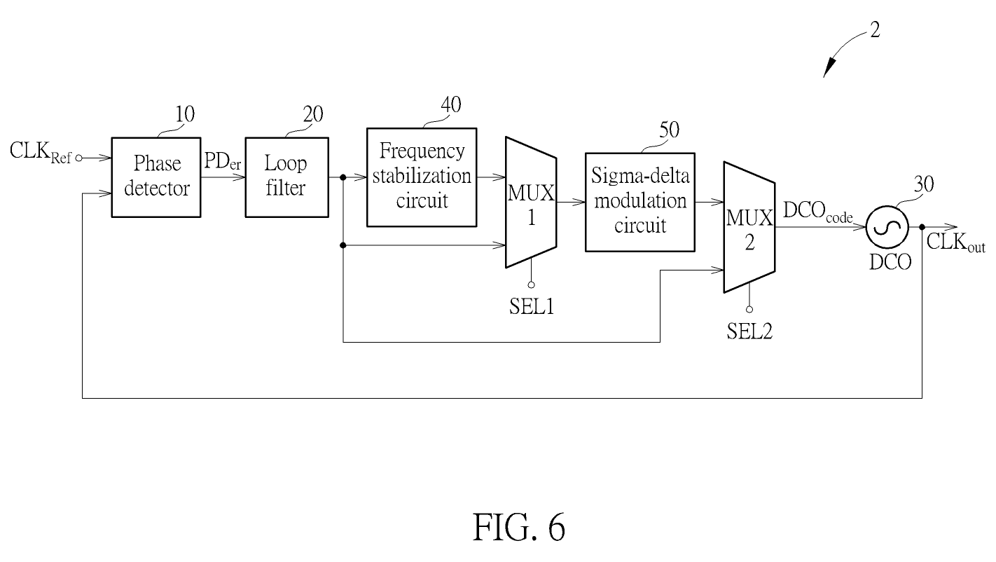

It should be noted that FIG. 1 is an embodiment of the present invention, and those skilled in the art may make appropriate adjustments according to the system requirements. To enhance the noise immunity of the phase-locked loop circuit of the present invention, the phase-locked loop circuit of the present invention may optionally include a frequency stabilization circuit and/or a sigma-delta modulation circuit. It should be noted that the phase-locked loop circuit described below is derived from phase-locked loop circuit 1, so the same components are represented by the same symbols. Please refer to FIG. 6, which is a schematic diagram of a phase-locked loop circuit 2 according to an embodiment of the present invention. The difference between the phase-locked loop circuit 2 and the phase-locked loop circuit 1 lies in the frequency stabilization circuit 40 and the sigma-delta modulation circuit 50. In this embodiment, the phase-locked loop circuit 2 can control the control terminals SEL1 and SEL of the multiplexers MUX1 and MUX2, enabling the digital control oscillator 30 to be directly coupled to the loop filter 20 or through one or more of the frequency stabilization circuit 40 and the sigma-delta modulation circuit 50.

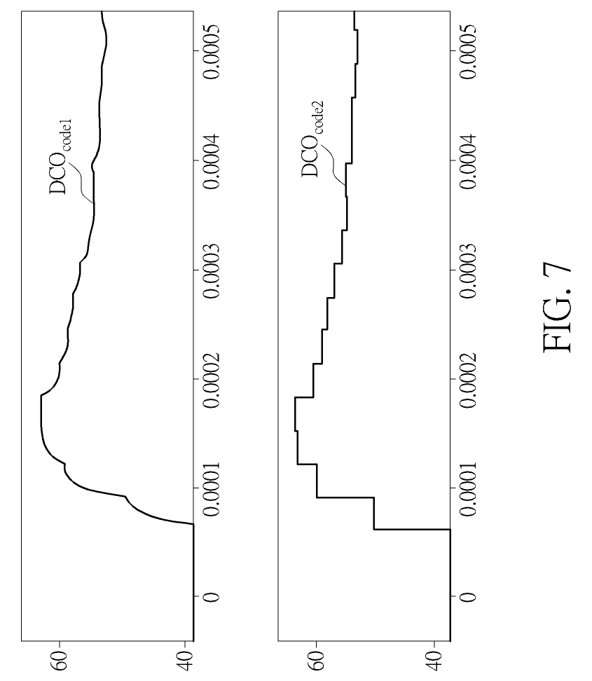

In an embodiment, the digital control oscillator 30 is coupled to the loop filter 20 through the frequency stabilization circuit 40. The frequency stabilization circuit 40 can perform a filtering processing or an integration processing to the at least one first phase error code and output at least one second phase error code as at least one control code DCO_{code}. Please refer to FIG. 7, which is a waveform diagram of the at least one first phase error code and the at least one second phase error code according to an embodiment of the present invention. As shown in FIG. 7, compared to the at least one first phase error code DCO_{code1}, the waveform of the at least one second phase error code DCO_{code2} has a smoother waveform change. As a result, when at least one second phase error code DCO_{code2} is used as at least one control code DCO_{code} to control the digital control oscillator 30 to generate an output clock signal CLKₒᵤₜ, the phase-locked loop circuit 2 exhibits improved noise immunity.

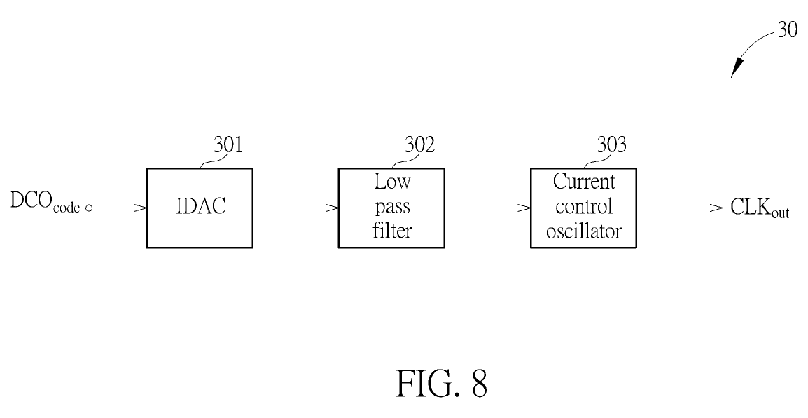

In another embodiment, the digital control oscillator 30 is coupled to the loop filter 20 through the sigma-delta modulation circuit 50. The sigma-delta modulation circuit 50 can transfer the quantization error of the at least one first phase error code to a high-frequency band and output the at least one third phase error code as the at least one control code DCO_{code}. In other words, the quantization noise in the low-frequency band is reduced, and the output clock signal CLKₒᵤₜ does not deviate from the target frequency for an extended period. It should be noted that, in this embodiment, as shown in FIG. 8, the digital control oscillator 30 may include a current digital to analog converter (IDAC) 301, a low-pass filter 302, and a current control oscillator 303. The current digital to analog converter 301 is configured to transfer the at least one third-phase error code which serves as the at least one control code DCO_{code}, into the at least one control current. The low-pass filter 302 is coupled between the current digital-to-analog converter 301 and the current control oscillator 303, and is configured to filter out quantization errors in the high-frequency band of the at least one control current, thereby driving the current control oscillator 303 to generate the output clock signal CLKₒᵤₜ. It should be noted that the filtering processing or the integration processing of the frequency stabilization circuit 40 and the operation principle of the sigma-delta modulation circuit 50 are well known in the art and are not repeated here.

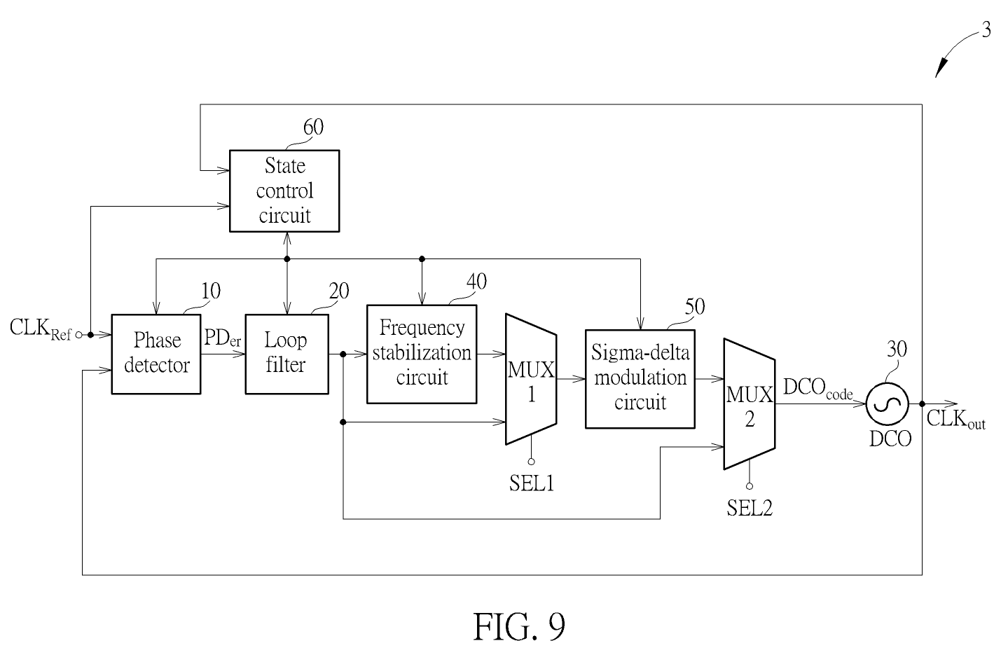

Furthermore, the phase detector 10, loop filter 20, frequency stabilization circuit 40, and sigma-delta modulation circuit 50 of the phase-locked loop circuit 2 of the present invention are all implemented using digital circuits. Therefore, the phase-locked loop circuit 2 can utilize the advantage of rapid adjustment of the digital circuits to control the phase-locked loop circuit 2 to meet different requirement specifications. Please refer to FIG. 9, which is a schematic diagram of a phase-locked loop circuit 3 according to an embodiment of the present invention. The difference between the phase-locked loop circuit 3 and the phase-locked loop circuit 2 is that the phase-locked loop circuit 3 further includes a state control circuit 60. The state control circuit 60 is coupled to the phase detector 10, the loop filter 20, the frequency stabilization circuit 40, and the sigma-delta modulation circuit 50 to control the output of phase detector 10 or adjust the parameter settings of loop filter 20, frequency stabilization circuit 40, and sigma-delta modulation circuit 50 according to different requirement specifications.

In an embodiment, when the first clock signal CLK_{Ref} fails, the state control circuit 60 can control the phase detector 10, the loop filter 20, the frequency stabilization circuit 40, and the sigma-delta modulation circuit 50 to continue outputting the corresponding signals, enabling the phase-locked loop circuit 3 to continue outputting the output clock signal CLKₒᵤₜ. In another embodiment, when the phase-locked loop circuit 3 has entered the locked state, the state control circuit 60 can disable the first clock signal CLK_{Ref} and control the phase detector 10, loop filter 20, frequency stabilization circuit 40, and sigma-delta modulation circuit 50 to continue outputting corresponding signals, enabling the phase-locked loop circuit 3 to continue outputting the output clock signal CLKₒᵤₜ. In another embodiment, when the first clock signal CLK_{Ref} experiences excessive noise or sudden phase changes, the state control circuit 60 can control the phase detector 10, the loop filter 20, the frequency stabilization circuit 40, and the sigma-delta modulation circuit 50 to continue outputting the corresponding signals (e.g., the signal from the previous cycle in the locked state), enabling the phase-locked loop circuit 3 to continue outputting the output clock signal CLKₒᵤₜ.

In another embodiment, when the requirement specification requires the phase-locked loop circuit 3 to enter a fast lock mode, the state control circuit 60 can adjust the parameters of the loop filter 20 to increase the bandwidth and reduce the lock time of the phase-locked loop circuit 3. After the phase-locked loop circuit 3 enters the locked state, the state control circuit 60 can adjust the parameters of the loop filter 20 to reduce the bandwidth, thereby reducing the jitter of the first clock signal CLK_{R}_{ef}on the phase-locked loop circuit 3. In another embodiment, the state control circuit 60 can record the at least one control code DCO _{code}corresponding to the target frequency of the locked output clock signal CLKₒᵤₜwhen the phase-locked loop circuit 3 enters the locked state. When the phase-locked loop circuit 3 begins operation, the state control circuit 60 can adjust the parameters of the loop filter 20, the frequency stabilization circuit 40, and the sigma-delta modulation circuit 50 to make the initial at least one control code DCO_{code} approach the at least one control code DCO_{code} corresponding to the target frequency. As a result, the lock time of the phase-locked loop circuit 3 can be significantly reduced.

In summary, the phase-locked loop circuit of the present invention implements the architecture of a phase-locked loop circuit using digital circuits. In this way, the phase-locked loop circuit can generate the output clock signal aligned with the reference clock signal while retaining the advantages of digital circuits, such as fast adjustment and fast implementation.

Those skilled in the art will readily observe that numerous modifications and alterations of the device and method may be made while retaining the teachings of the invention. Accordingly, the above disclosure should be construed as limited only by the metes and bounds of the appended claims.

What is claimed is:

1. A phase-locked loop (PLL) circuit, comprising:
a digital control oscillator, configured to generate an output clock signal according to at least one control code generated using at least one phase error signal; and
a phase detector, configured to generate the at least one phase error signal according to a rising edge difference and a rising edge lead-lag relation between a rising edge of a first clock signal and a corresponding edge of an edge alignment corrected feedback signal;
wherein the edge alignment corrected feedback signal is generated based on the output clock signal.

2. The PLL circuit of claim 1, wherein the phase detector comprises:
a counter, configured to generate the edge alignment corrected feedback signal according to the output clock signal;
an edge sampler, configured to generate a first sampled signal corresponding to the rising edge and a second sampled signal corresponding to the rising edge lead-lag relation according to the first clock signal and the output clock signal; and
a phase quantization circuit, coupled to the counter and the edge sampler, configured to generate the at least one phase error signal according to the first sampled signal, the second sampled signal and the edge alignment corrected feedback signal.

3. The PLL circuit of claim 2, wherein the edge sampler comprises:
a first D flip-flop circuit, comprising a first clock input terminal, a first data input terminal and a first data output terminal;
a second D flip-flop circuit, comprising a second clock input terminal, a second data input terminal and a second data output terminal;
a third D flip-flop circuit, comprising a third clock input terminal, a third data input terminal and a third data output terminal;
wherein the first clock input terminal, the second clock input terminal and the third clock input terminal are configured to receive the output clock signal, the first data input terminal is configured to receive the first clock signal, the first data output terminal is configured to output a first data output signal to the second data input terminal and, the second data output terminal is configured to output a second data output signal to the third data input terminal, and the third data output terminal is configured to output a third data output signal;
a determination circuit, configured to receive the second data output signal and the third data output signal to generate the first sampled signal;
a NOT gate circuit, configured to receive the output clock signal to generate an inverted output clock signal;
a fourth D flip-flop circuit, comprising a fourth clock input terminal, a fourth data input terminal and a fourth data output terminal;
a fifth D flip-flop circuit, comprising a fifth clock input terminal, a fifth data input terminal and a fifth data output terminal;
a sixth D flip-flop circuit, comprising a sixth clock input terminal, a sixth data input terminal and a sixth data output terminal;
wherein the fourth clock input terminal is configured to receive the inverted output clock signal, the fifth clock input terminal and the sixth clock input terminal are configured to receive the output clock signal, the fourth data input terminal is configured to receive the first clock signal, the fourth data output terminal is configured to output a fourth data output signal to the fifth data input terminal and, the fifth data output terminal is configured to output a fifth data output signal to the sixth data input terminal, and the sixth data output terminal is configured to output a sixth data output signal; and
a NAND gate circuit, configured to receive the first sampled signal and the sixth data output signal to generate the second sampled signal.

4. The PLL circuit of claim 2, further comprising:
a loop filter, coupled between the phase detector and the digital control oscillator, configured to generate a first phase error code according to the at least one phase error signal.

5. The PLL circuit of claim 4, further comprising:
a frequency stabilization circuit, coupled between the loop filter and the digital control oscillator, configured to generate the at least one control code according to the first phase error code.

6. The PLL circuit of claim 4, further comprising:
a sigma-delta modulation circuit, coupled between the loop filter and the digital control oscillator, configured to generate the at least one control code according to the first phase error code.

7. The PLL circuit of claim 6, wherein the digital control oscillator comprises:
a current digital to analog converter, configured to convert the at least one control code to at least one control current;
a low-pass filter; coupled to the current digital to analog converter; and
a current control oscillator; configured to be driven by the low-pass filter to generate the output clock signal according to the at least one control current.

8. A phase detector, for a phase-locked loop (PLL) circuit, comprising:
a counter, configured to generate an edge alignment corrected feedback signal according to an output clock signal of the PLL circuit;
an edge sampler, configured to generate a first sampled signal corresponding to a rising edge of a first clock signal of the PLL circuit and a second sampled signal corresponding to a rising edge lead-lag relation between the rising edge of the first clock signal and a corresponding edge of the edge alignment corrected feedback signal according to the first clock signal and the output clock signal; and
a phase quantization circuit, coupled to the counter and the edge sampler, configured to generate at least one phase error signal according to the first sampled signal, the second sampled signal and the edge alignment corrected feedback signal.

9. The phase detector of claim 8, wherein the edge sampler comprises:
a first D flip-flop circuit, comprising a first clock input terminal, a first data input terminal and a first data output terminal;
a second D flip-flop circuit, comprising a second clock input terminal, a second data input terminal and a second data output terminal;
a third D flip-flop circuit, comprising a third clock input terminal, a third data input terminal and a third data output terminal;
wherein the first clock input terminal, the second clock input terminal and the third clock input terminal are configured to receive the output clock signal, the first data input terminal is configured to receive the first clock signal, the first data output terminal is configured to output a first data output signal to the second data input terminal and, the second data output terminal is configured to output a second data output signal to the third data input terminal, and the third data output terminal is configured to output a third data output signal;
a determination circuit, configured to receive the second data output signal and the third data output signal to generate the first sampled signal;
a NOT gate circuit, configured to receive the output clock signal to generate an inverted output clock signal;
a fourth D flip-flop circuit, comprising a fourth clock input terminal, a fourth data input terminal and a fourth data output terminal;
a fifth D flip-flop circuit, comprising a fifth clock input terminal, a fifth data input terminal and a fifth data output terminal;
a sixth D flip-flop circuit, comprising a sixth clock input terminal, a sixth data input terminal and a sixth data output terminal;
wherein the fourth clock input terminal is configured to receive the inverted output clock signal, the fifth clock input terminal and the sixth clock input terminal are configured to receive the output clock signal, the fourth data input terminal is configured to receive the first clock signal, the fourth data output terminal is configured to output a fourth data output signal to the fifth data input terminal and, the fifth data output terminal is configured to output a fifth data output signal to the sixth data input terminal, and the sixth data output terminal is configured to output a sixth data output signal; and
a NAND gate circuit, configured to receive the first sampled signal and the sixth data output signal to generate the second sampled signal.
